(19) United States
(12) Patent Application Publication
(10) Pub. No.: US 2007/0115006 A1
(43) Pub. Date: May 24, 2007

(54) Capacitor screening

(75) Inventors: Casey Okezie Anude, San Diego, CA (US); Bruce Allen Brentlinger, San Diego, CA (US)

Correspondence Address: HENSLEY KIM & EDGINGTON, LLC, 1660 LINCOLN STREET, SUITE 3050, DENVER, CO, 80264-3103, US

(73) Assignee: Maxwell Technologies, Inc., San Diego, CA (US)

(21) Appl. No.: 11/602,526

(22) Filed: Nov. 21, 2006

Related U.S. Application Data
(60) Provisional application No. 60/739,402, filed on Nov. 22, 2005.

(51) Int. Cl. G01R 27/26

(52) U.S. Cl. 324/678

(57) ABSTRACT

Systems and methods for screening capacitors are disclosed. An exemplary method may comprise charging at least one capacitor for time t1 and then implementing the following operations. After charging time t1, comparing a charge state of the at least one capacitor to thresholds th1-low and th1-high for a capacitance screening operation. After waiting time t2, comparing the charge state of the at least one capacitor to a threshold th2 for an Equivalent Series Resistance (ESR) screening operation. After waiting time t3, comparing a change in the charge state of the at least one capacitor to a threshold th3 for a Leakage Current (LC) and Self-Discharge (SD) screening operation. The screening operations may be implemented manually by a user and/or automatically by the exemplary system described herein.

### BACKGROUND

The present invention generally relates to capacitors. More specifically, the present invention relates to systems and methods for screening capacitors.

Capacitors are commonly used to store electrical energy for a wide variety of electronic devices. For a number of reasons, compound capacitors, also known as “double layer capacitors,” “super-capacitors,” and “ultra-capacitors,” are gaining popularity in many energy storage applications. The reasons include availability of compound capacitors with high power densities (in both charge and discharge modes), and with energy densities approaching those of conventional rechargeable cells.

Important characteristics of these capacitors include total capacitance, Equivalent Series Resistance (ESR), Leakage Current (LC), and/or Self-Discharge (SD). Manufacturers may employ a self-discharge profile during a testing/auditing stage to determine these characteristics for capacitors prior to shipping/delivering the capacitors to their customers so that “bad” capacitors are not shipped. However, the testing/auditing stage typically requires several hours (e.g., 12 hours for every 256 capacitors) to complete, delaying shipments and increasing costs.

A need thus exists for determining various characteristics of capacitors, including but not limited to total capacitance, Equivalent Series Resistance (ESR), Leakage Current (LC), and/or Self-Discharge (SD), prior to shipping/delivery that is both fast and accurate.

### SUMMARY

Various implementations are provided for systems and methods for screening capacitors, including but not limited to, compound capacitors (e.g., “super-capacitors,” “double layer capacitors,” and “ultra-capacitors”) that may be directed to or may satisfy one or more of the above needs.

An exemplary system for screening capacitors comprises a power supply electrically coupled to a connector for receiving at least one capacitor. A controller is operatively associated with the power supply and the connector. The controller can selectively apply an electrical signal from the power supply to the at least one capacitor. In response, the controller receives an electrical input representing a charge state of the at least one capacitor. Logic instructions are executable by the controller. The logic instructions compare the charge state of the at least one capacitor to at least one threshold for identifying satisfactory and failed capacitors.

An exemplary method for screening capacitors may comprise applying an electrical signal to at least one capacitor, receiving electrical input representing a charge state of the at least one capacitor, comparing the charge state of the at least one capacitor to at least one threshold, and identifying satisfactory and failed capacitors based on the comparison operation.

Another exemplary method for screening capacitors may comprise charging at least one capacitor and then implementing the following operations. After charging the capacitor for time t1, comparing a charge state of the at least one capacitor to thresholds th1-low and th1-high for a capacitance screening operation. After waiting time t2, comparing the charge state of the at least one capacitor to a threshold th2 for an Equivalent Series Resistance (ESR) screening operation. After waiting time t3, comparing a change in the charge state of the at least one capacitor to a threshold th3 for a Leakage Current (LC) and Self-Discharge (SD) screening operation.

The systems and methods may be implemented manually and/or automatically, as described herein. The systems and methods may be used to screen multiple capacitors simultaneously and distinguish “good” capacitors from “bad” capacitors quickly (e.g., on the order of seconds). In addition, only a single charge and removal step is needed, reducing or altogether eliminating hold times during the manufacture process. In exemplary implementations, the systems and methods may be implemented as a “gate” in the manufacturing process, wherein all capacitors or a statistically significant portion of the capacitors are screened before passing onto the next stage (e.g., labeling, shipping/distribution) as a quality control measure.

### BRIEF DESCRIPTION OF THE DRAWINGS

FIG. 1 shows a high-level block diagram of an exemplary test system that may be implemented for screening capacitors.

FIG. 2 shows a process flow diagram illustrating exemplary data operations that may be implemented for screening capacitors.

FIG. 3 shows a process flow diagram illustrating exemplary mechanical operations that may be implemented for screening capacitors.

FIG. 4 shows an overview flowchart illustrating exemplary operations for screening capacitors.

FIG. 5 shows a flowchart illustrating exemplary operations for screening capacitors for capacitance.

FIG. 6 shows a flowchart illustrating exemplary operations for screening capacitors for Equivalent Series Resistance (ESR).

FIG. 7 shows a flowchart illustrating exemplary operations for screening capacitors for Leakage Current (LC) and/or Self-Discharge (SD).

### DETAILED DESCRIPTION

In this document, the words “implementation” and “variant” may be used to refer to a particular apparatus, process, or article of manufacture, and not necessarily always to one and the same apparatus, process, or article of manufacture. Thus, “one implementation” (or a similar expression) used in one place or context can refer to one particular apparatus, process, or article of manufacture; and, the same or a similar expression in a different place can refer either to the same or to a different apparatus, process, or article of manufacture. Similarly, “some implementations,” “certain implementations,” or similar expressions used in one place or context may refer to one or more particular apparatuses, processes, or articles of manufacture; the same or similar expressions in a different place or context may refer to the same or a different apparatus, process, or article of manufacture. The expression “alternative implementation” and similar phrases are used to indicate one of a number of different possible implementations. The number of possible implementations is not necessarily limited to two or any other quantity. Characterization of an implementation as “an exemplar” or “exemplary” means that the implementation is used as an example. Such characterization does not necessarily mean that the implementation is a preferred implementation; the implementation may but need not be a currently preferred implementation.

Other and further definitions and clarifications of definitions may be found throughout this document. The definitions are intended to assist in understanding this disclosure and the appended claims, but the scope and spirit of the invention should not be construed as limited to the particular examples described in this specification. Indeed, the methods and systems disclosed herein are scalable to test for capacitance, equivalent series resistance (ESR), leakage current (LC), and self-discharge (SD) for capacitors having varying nominal capacitance levels. While particular examples are described for screening capacitors having one or more nominal capacitance value, one skilled in the art would readily appreciate that the parameters of the screening process(es) (e.g., the threshold levels, charging current levels, voltage levels, and time period durations) may be altered for screening capacitors having higher or lower nominal capacitance values.

Reference will now be made in detail to several implementations of the invention that are illustrated in the accompanying drawings. The same reference numerals are used in the drawings and the description to refer to the same or substantially the same parts or operations. The drawings are in simplified form and not to precise scale. For purposes of convenience and clarity only, directional terms, such as top, bottom, left, right, up, down, over, above, below, beneath, rear, and front may be used with respect to the accompanying drawings. These and similar directional terms, should not be construed to limit the scope of the invention.

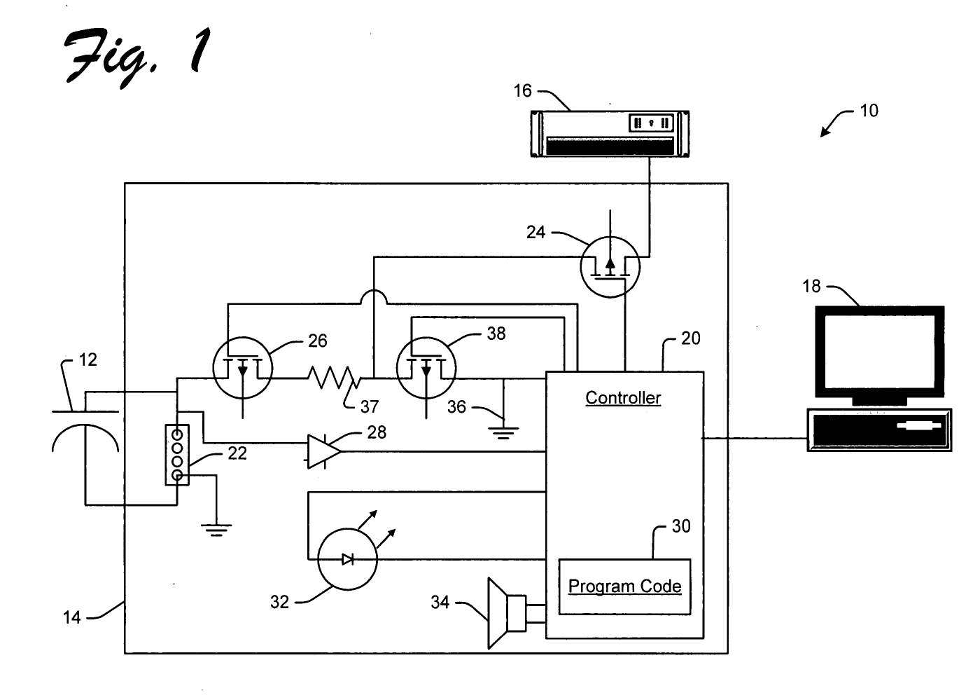

FIG. 1 shows a high-level block diagram of an exemplary test system 10 that may be implemented for screening capacitors 12. The exemplary system 10 may be implemented as an electronic device, e.g., on a printed circuit board or “PCB” 14. The PCB 14 may be a stand-alone device or may be connected to an external power supply 16 and/or a host computer 18.

The PCB 14 may include various components controlled by a controller 20. In an exemplary implementation, the controller 20 is a microcontroller, such as, PIC18F8722 64/80-pin, 1 M-bit Enhanced Flash Microcontroller with a 10 bit A/D converter readily commercially available from Microchip Technology Inc., 2355 West Chandler Blvd., Chandler, Ariz. 85244-6199. However, the controller 20 is not limited to any particular design configuration and other controllers (including personal computers) may be implemented in other implementations.

The controller 20 is operatively associated with one or more connector 22, which may be provided for receiving at least one capacitor 12 for the screening operations. In an exemplary implementation, the connector 22 may be a zero insertion force (ZIF) connector or a general probe, such as an IDI R-4 receptacle soldered on the board and a matching S-4 probe that plugs into the receptacle readily commercially available from Interconnect Devices, Inc., 5101 Richland Avenue, Kansas City, Kans. 66106. Accordingly, a robotic mechanism may readily insert and remove the capacitor 12 (or a pallet of capacitors) without the need for manual intervention. However, the connector 22 is not limited to any particular design configuration.

The controller 20 is also operatively associated with the power supply 16. Power supply 16 may be implemented as a DC 2.5 volt 40 amp power supply (e.g., for screening 32 nominal 10 F capacitance cells), such as an HP model 6551A power supply readily commercially available from Agilent Technologies, Inc., 5301 Stevens Creek Blvd., Santa Clara, Calif. 95051. During operation, the controller 20 selectively applies an electrical signal from the power supply 16 to the at least one capacitor 12 via a power switch 24. For example, the electrical signal may be a current source that charges the capacitor 12 via a charging switch 26, which is also controlled by the controller 20.

At various times during the screening operations, the controller 20 receives an electrical input representing a charge state of the at least one capacitor 12 via high impedance amplifier 28. Logic instructions implemented as program code 30 (e.g., software and/or firmware) are executable by the controller 20 to compare the charge state of the capacitor 12 to at least one threshold for identifying satisfactory and failed capacitors, as will be described in more detail below.

After completing the screening operation(s), controller 20 may optionally discharge the capacitor 12. For example, the controller 20 may operate a discharge switch 38 to discharge the capacitor 12 by shorting it to ground 36 via a resistor 37.

Test data corresponding to the various screening operations may be processed by the controller 20 and output, e.g., by lighting one or more light emitting diode (LED) 32 or other display device, sounding an alarm at speaker 34, delivering the data to the host computer 18, and/or any other output operation.

The host computer 18 may be implemented as any suitable computing device including one or more processors or processing units and other system components, such as, e.g., memory or other computer readable storage. Exemplary computing devices include, but are not limited to, desktop and laptop personal computers (PCs), server computers, and personal digital assistants (PDAs). It is noted that in exemplary implementations, the computing device may be implemented in a computer network (not shown), such as, e.g., a local area network (LAN) and/or wide area network (WAN).

The host computer 18 may also include a suitable user interface, such as a graphical user interface (GUI) to facilitate user interaction with the system 10. In exemplary implementations, the host computer 18 may be used to review and manipulate (e.g., generate reports) the data received from controller 20. The host computer 18 may also be used to configure the controller 20 (e.g., changing threshold values, timing, etc.). These and other functions may be readily implemented by those having ordinary skill in the computer arts after becoming familiar with the teachings herein.

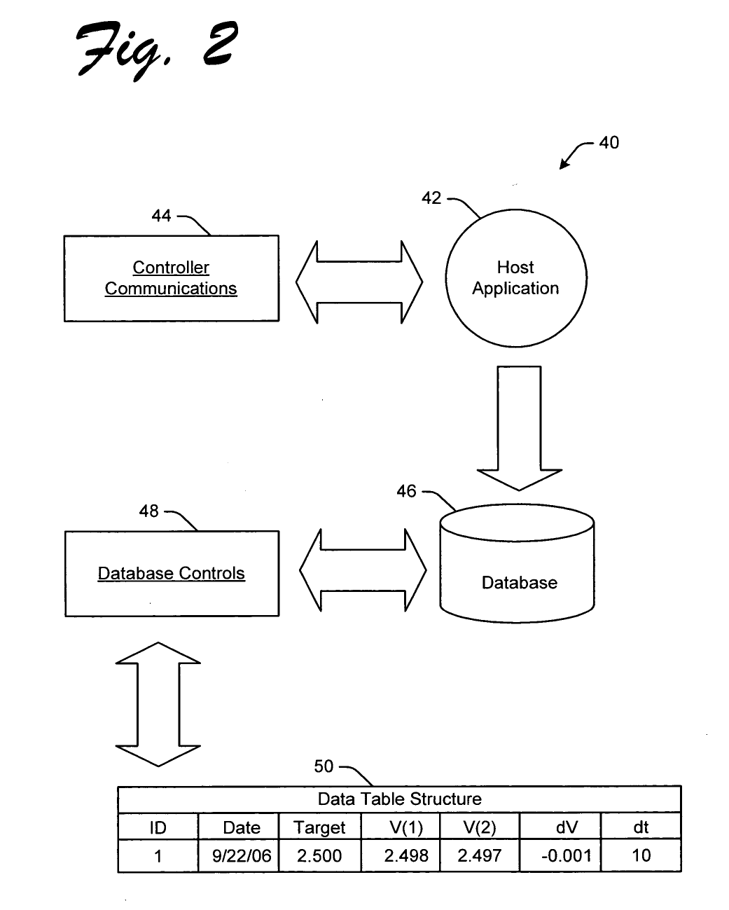

FIG. 2 shows a process flow diagram illustrating exemplary data operations 40 which may be implemented for screening capacitors (e.g., capacitor 12 shown in FIG. 1). A host application 42 may be implemented as software executing on the host computer 18. Host application 42 may communicate with the controller 20 to receive test data, reset (or erase test data at the controller 20), set or change one or more settings of the controller 20, such as thresholds and/or wait times for the screening operations, etc., (collectively illustrated in FIG. 2 as controller communications 44).

The host application 42 may also implement a database 46 (or other data structure). As discussed above, the user may manipulate the test data (e.g., to generate reports) using database controls 48. Accordingly, the test data and/or manipulated data may be stored in the database 46 for use for any of a wide variety of different analysis and functions (e.g., manufacturing changes, quality control, etc.).

An exemplary data table structure 50 is also shown in FIG. 2 as it may be used to store the test data and/or manipulated data. The data table structure 50 includes a capacitor identification, test date, target charge state, measured charge states (V1 and V2), measured changes in charge state (dV) and time for the test (dt). It is noted that while an exemplary data table structure 50 is provided for purposes of illustration, the systems and methods described herein are not limited to use with any particular type and/or format of test data.

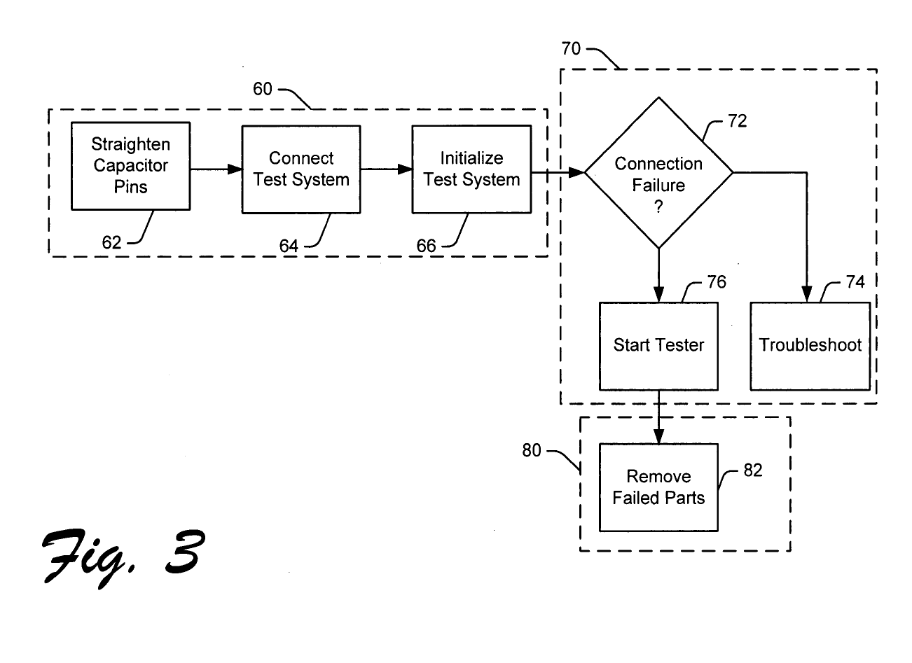

FIG. 3 shows a process flow diagram illustrating exemplary mechanical operations which may be implemented for screening capacitors. The mechanical operations may include generally a preparation stage 60, a screening stage 70, and a finishing stage 80.

In the preparation stage 60, the capacitors may be prepped for the screening stage 70. For example, the capacitor pins may be straightened, as illustrated by block 62, so that the pins can be readily connected to the test system (e.g., inserted into the connector 22 in FIG. 1) for the screening operations. The pins may be straightened manually or automatically, e.g., using a robotic mechanism.

Also in the preparation stage 60, the capacitor(s) may be connected to the test system (e.g., the connector 22 on the PCB 14 in FIG. 1) as illustrated by block 64. The capacitor may be connected to the test system manually or automatically, e.g., using a robotic mechanism. In an exemplary implementation, a robotic mechanism may lower the test system onto a pallet having 32 capacitors. In addition, capacitors may be connected to the test system individually, or in groups (e.g., on pallets).

The test system may also be initialized in the preparation stage 60, as illustrated by block 66. For example, the controller may be configured with thresholds, test times, test conditions (e.g., whether to use an electrical contact or logic-level output). It is noted that the initializing 66 may occur after pin straightening 62 and/or connecting 64 of the capacitor(s) to the test system, prior to pin straightening 62 and/or connecting 64 of the capacitors(s) to the test system, or simultaneously with one or more of these procedures.

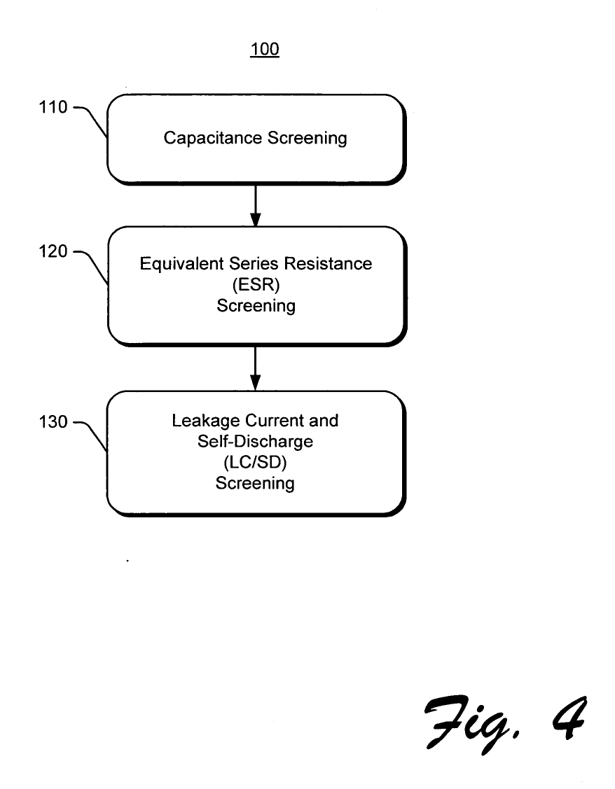

In the screening stage 70, a determination is made whether the capacitors are properly connected to the test system, as illustrated by block 72. For example, if there is a connection failure in the same location for three consecutive tries (or other predetermined number of tries), a failure status may be issued to the controller. If one or more of the capacitors are not connected properly (e.g., not properly seated to connector 22 in FIG. 1), then the problem is troubleshot as illustrated by block 74. For example, a robotic mechanism may automatically attempt to re-seat the capacitor without user intervention. Alternatively for example, a user may manually inspect and correct the problem. If the capacitors are properly connected, the capacitors are screened (e.g., using test system 10 in FIG. 1, or manually by a user), as illustrated by block 76. The test system completes the test and sends status and test data to the controller. In an exemplary implementation, this occurs in under one minute, and more particularly, in about 48 seconds based on a line speed of 1.5 seconds per capacitor for a pallet of 32 capacitors. Exemplary operations are described in more detail below with reference to FIGS. 4-7.

In the finishing stage 80, the capacitors may be removed from the test system and bad capacitors may be rejected, as illustrated by block 82. The capacitor(s) that failed the screening may be discarded manually, automatically (e.g., using a robotic mechanism), or using some combination thereof. The capacitors that passed the screening may be moved to the next stage, e.g., labeling, packaging, shipping/distribution, etc.

Having described exemplary systems for screening capacitors, and methods for preparing the capacitors for the screening operations, the screening operations will now be described in more detail with reference to FIGS. 4-7. It is noted that the operations in FIGS. 4-7 may be embodied as logic instructions on one or more computer-readable medium. When executed on a processor (e.g., the controller 20), the logic instructions cause a general purpose computing device to be programmed as a special-purpose machine that implements the described operations. Alternatively, at least some of the operations in FIGS. 4-7 may be implemented manually by a user without the need for a specialized test system such as the test system 10 shown in FIG. 1.

FIG. 4 shows an overview flowchart illustrating exemplary operations 100 for screening capacitors. In operation 110, one or more capacitor is screened for capacitance. In operation 120, one or more capacitor is screened for Equivalent Series Resistance (ESR). In operation 130, one or more capacitor is screen for Leakage Current (LC) and Self-Discharge (SD).

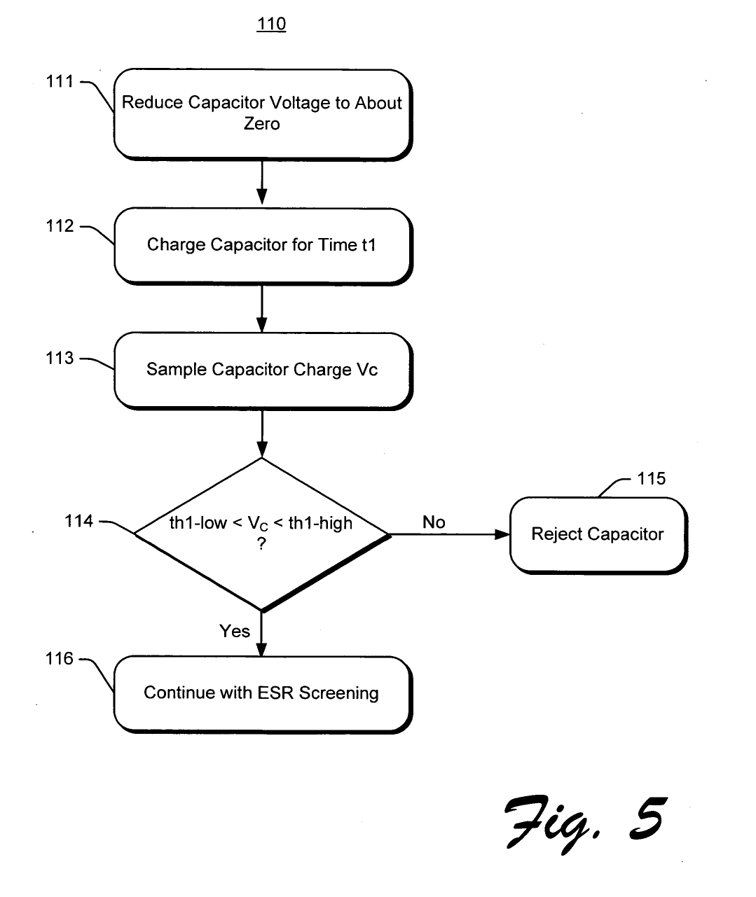

Each of the operations 110, 120, and 130 are described in more detail below with reference to FIGS. 5, 6, and 7, respectively. Briefly, however, capacitance screening 110 may include comparing a charge state of at least one capacitor to a threshold th1-low and th1-high after charging for time t1. ESR screening 120 may include comparing a charge state of the at least one capacitor to a threshold th2 after waiting time t2. LC and SD screening may include comparing a change in the charge state of the at least one capacitor to a threshold th3 after waiting time t3. As described above, the operations 110, 120, and 130 are each scalable and operating parameters (e.g., the threshold levels, charging current levels, voltage levels, and time period durations) may be altered from the examples provided to screen capacitors having higher or lower nominal capacitance values.

Before continuing, it is noted that the operations 110, 120, and 130 are not limited to any particular order. Nor do each of the operations 110, 120, and 130 have to be implemented all of the time. In other implementations, one or more of the operations 110, 120, and 130 may be implemented. In addition, the operations 110, 120, and 130 may be implemented more than one time for each capacitor(s).

FIG. 5 shows a flowchart illustrating exemplary operations 110 for screening capacitors for capacitance. In a capacitance screening operation, for example, the duration of time it takes to charge a capacitor from a known initial voltage (e.g., approximately 0 volts) under a known current to reach a predetermined target voltage can be an indicator of the capacitance of the capacitor. The change in charge of the capacitor ΔQ=I•ΔT=C•ΔV, where I is the constant current used in charging the capacitor, ΔT is the charging time, and ΔV is the voltage. Thus, if a capacitor is charged from a known initial voltage at a constant current for a predetermined time period, the resulting voltage of the capacitor can be compared to at least one threshold voltage to determine if the capacitance of the cell meets a minimum threshold for the for the capacitance and a second threshold voltage to determine if the capacitance of the cell is greater than a maximum threshold for the capacitance.

In the particular implementation shown in FIG. 5, for example, the capacitor voltage is reduced to about zero in operation 111. For example, the capacitor may be shorted to ground to discharge it. It is noted, however, this operation 111 is optional. Alternatively, the initial charge may be determined and used as a baseline charge state of the capacitor. For example, if the initial charge is about 15-20 mV, this may be used as a baseline charge state of the capacitor.

In operation 112, the capacitor is charged for a predetermined time t1. In an exemplary implementation, the capacitor is charged with a known current (e.g., 1 Amp DC) for a predetermined time t1 (e.g., 10 seconds). The charge state of the capacitor is then determined in operation 113 (e.g., via the high impedance amplifier 28 shown in FIG. 1). The charge state of the capacitor should (if it is “good”) increase to a predetermined charge state. For example, for a capacitor whose nominal capacitance is 10 Farad, the charge state should be about 1 V if the capacitor was completely discharged in operation 111, or the charge state should be about 1.015 V if the baseline charge state was 15 mV. Of course, there parameters are scalable for screening capacitors having higher or lower nominal capacitance values than the example 10 Farad capacitor. If the capacitor was not discharged to 0 V in operation 111, the baseline charge may be subtracted from the sampled voltage obtained in sampling operation 113 to determine the change in the charge state of the capacitor ΔVc due to the charging operation 112.

In operation 114, a determination is made whether the charge state of the capacitor due to the charging operation 112 (Vc or ΔVc) is between a threshold th1-low and th1-high. The thresholds th1-low and th1-high may be selected based on a wide variety of design considerations, including but not limited to, the desired tolerances for the capacitor being screened. In an exemplary implementation, the tolerances are plus/minus 20%. Accordingly, any capacitor not meeting these tolerances may be rejected in operation 115. Any capacitor meeting these tolerances may continue with the ESR screening, as indicated by operation 116.

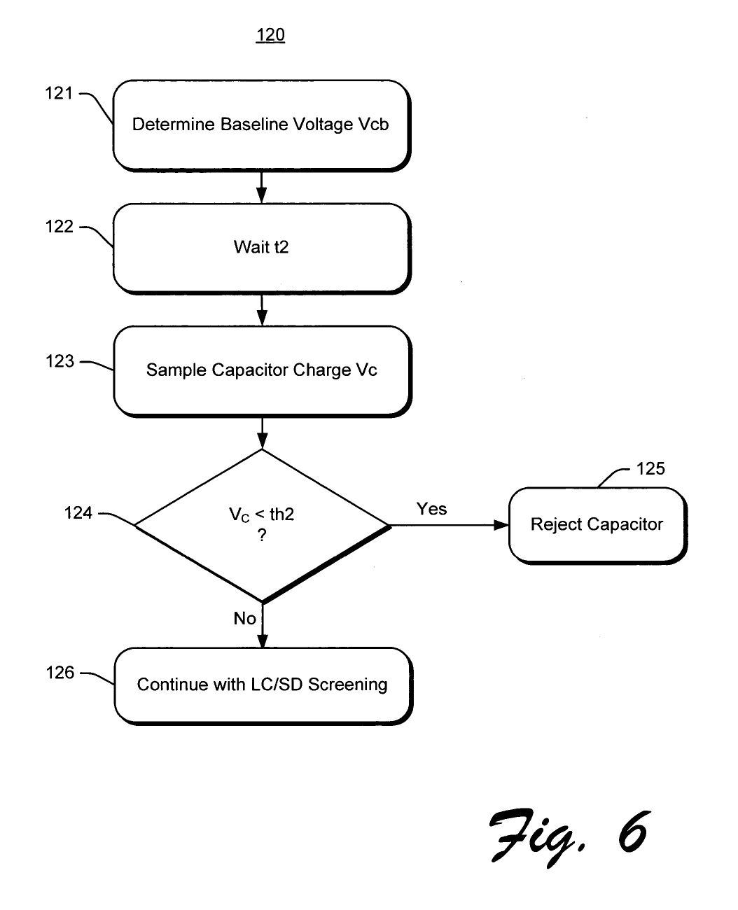

FIG. 6 shows a flowchart illustrating exemplary operations 120 for screening capacitors for Equivalent Series Resistance (ESR). In an ESR screening operation, when a capacitor being charged (as in the capacitance screening operation described above with respect to FIG. 5) is disconnected from the charging current, the capacitor experiences a sudden voltage drop that is related to the ESR of the capacitor. The higher the ESR of the capacitor, the steeper the voltage drop that the capacitor experiences. In particular, the ESR can be modeled by the following equation: ESR=ΔV/I, where ΔV is the sudden change in voltage experienced by the capacitor upon the charging current withdrawal and I is the known constant charging current. Thus, a capacitor may be screened for ESR by charging the capacitor as described above in the capacitance screening operation and disconnecting the capacitor from the charging current. After the charging current has been disconnected from the capacitor the voltage drop due to the removal of the charging current may be determined over a predetermined time period and compared to a threshold voltage drop to determine if the ESR of the capacitor has caused the voltage to drop too far in the predetermined time period. In another implementation, however, the voltage level of the capacitor detected after the charging current has been disconnected and a predetermined time period has passed may be compared to a voltage threshold representing an acceptable voltage level that would correspond to a capacitor having an acceptable ESR value.

In the particular implementation of an ESR screening operation shown in FIG. 6, for example, a baseline voltage Vcb for the capacitor is determined in operation 121. For example, the capacitor may be discharged so that it has a voltage of about 0 V, and then the capacitor may be charged again (as explained above) so that it has a known baseline voltage. Alternatively, the existing charge of the capacitor (e.g., from capacitance screening operations 110) may be measured and used as the baseline voltage for the capacitor where the ESR screen is performed immediately after a capacitance screen.

In wait operation 122, a wait of a predetermined time period t2 is imposed. The charge state of Vc is then determined in sampling operation 123. In operation 124, a determination is made whether the capacitor's charge state Vc is less than a threshold th2. The threshold th2 may be selected based on a wide variety of design considerations, including but not limited to, the desired tolerances for the capacitor being screened. In an exemplary implementation for a capacitor having a nominal capacitance of 10 Farad in which a two-second wait (i.e., t2=2 seconds) is provided, a change in voltage of approximately 200 mV may be acceptable for particular applications. Thus, if the cell started at a voltage of 1 V, a threshold th2 of 0.8 V may be used. If the capacitor's charge state Vc is less than the threshold th2, the capacitor is rejected in operation 125 for failing the ESR screen. If the charge state Vc satisfies the threshold th2, the capacitor may continue with LC/SD screening, as indicated by operation 126. Again, there parameters are scalable for screening capacitors having higher or lower nominal capacitance values than the example 10 Farad capacitor.

In another implementation instead of comparing the sampled voltage Vc to the threshold th2, a change in the voltage from the baseline voltage Vcb to the voltage Vc may be determined and compared to another threshold (e.g., 200 mV).

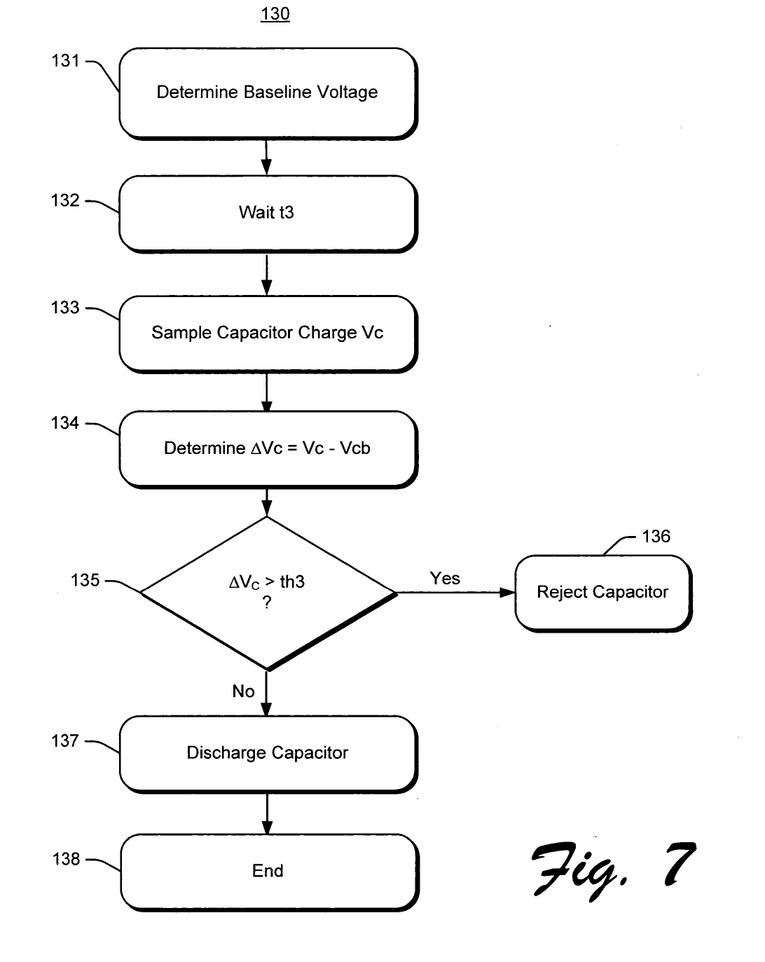

FIG. 7 is a flowchart illustrating exemplary operations 130 for screening capacitors for Leakage Current (LC) and/or Self-Discharge (SD). A capacitor will undergo a self-discharge when the capacitor is placed in an open-circuit voltage (OCV) condition. In contrast to the sudden drop in voltage observed when the capacitor is first disconnected from a constant charging current (described above with respect to the ESR screening operation), the capacitor placed in an OCV condition will experience a generally gradual, steady, and sustained loss of voltage or energy. The loss profile is generally asymptotic and is very high initially and tapers off as time progresses. A change in voltage observed over a predetermined time period beginning after the sudden drop due to the ESR of the capacitor may be compared to a voltage threshold to determine whether the self-discharge of the capacitor is acceptable. In one implementation, the predetermined time period is on the order of seconds to ensure that the inherent capacitance of the capacitor, which varies with the cell voltage, does not change significantly between measurements. The magnitude of this voltage change may be compared to a voltage threshold to determine if the LC and/or SD of the capacitor are acceptable.

In the particular implementation of an LC and/or SD screen shown in FIG. 7, a baseline voltage for the capacitor Vcb is determined in operation 131. For example, the capacitor may be discharged so that it has a voltage of about 0, and then the capacitor may be charged again (as explained above) so that it has a known baseline voltage. Alternatively, the existing charge of the capacitor (e.g., from ESR screening operations 120) may be measured and used as the baseline voltage for the capacitor. A predetermined wait time t3 is imposed in wait operation 132, and the charge state Vc is determined for the capacitor after time t3 in sampling operation 133. The change in the capacitor charge state ΔVc due to the wait time t3 imposed in operation 132 is then determined in operation 134 by subtracting the baseline voltage Vcb determined in operation 131 from the sampled voltage Vc determined in sampling operation 133.

In operation 135, a determination is made whether a change in the capacitor's charge state (ΔVc) during time t3 exceeds a threshold th3. The threshold th3 may be selected based on a wide variety of design considerations, including but not limited to, the desired tolerances for the capacitor being screened. In an exemplary implementation, a capacitor rated at 2.5 V with a nominal capacitance of 10 Farad, a 15 mV to 20 mV drop is acceptable for a ten-second wait (i.e., t3=10 seconds). If the change in the charge state delta Vc exceeds the threshold th3, the capacitor is rejected in operation 136. If the charge state Vc satisfies the threshold th3, the capacitor may optionally be discharged in operation 137 and screening ends in operation 138. Again, there parameters are scalable for screening capacitors having higher or lower nominal capacitance values than the example 10 Farad capacitor. A screening operation for a capacitor having a higher nominal capacitance value (e.g., a 2600 Farad or 3000 Farad capacitor) may impose a longer wait time t3 (e.g., on the order of minutes or hours).

The inventive systems and methods for screening capacitors have been described above in considerable detail for illustrative purposes. Neither the specific implementations of the invention as a whole, nor those of its features, limit the general principles underlying the invention. In particular, the invention is not necessarily limited to the specific sizes or configurations. The specific features described herein may be used in some implementations, but not in others, without departure from the spirit and scope of the invention as set forth. Many additional modifications are intended in the foregoing disclosure, and it will be appreciated by those of ordinary skill in the art that, in some instances, some features of the invention will be employed in the absence of other features. The illustrative examples therefore do not define the metes and bounds of the invention and the legal protection afforded the invention, which function is served by the claims and their equivalents.

1. A system for screening capacitors comprising:
a power supply electrically coupled to a connector for receiving at least one capacitor;
a controller operatively associated with the power supply and the connector, the controller selectively applying an electrical signal from the power supply to the at least one capacitor and selectively receiving an electrical input representing a charge state of the at least one capacitor; and
logic instructions executable by the controller, the logic instructions comparing a change in the charge state of the at least one capacitor over a predetermined time period to at least one threshold for screening the at least one capacitor for a Leakage Current (LC) and Self-Discharge (SD) of the at least one capacitor.

2. The system of claim 1 wherein the logic instructions:
compare a charge state of the at least one capacitor to thresholds th1-low and th1-high after charging for time t1 for capacitance screening;
compare a charge state of the at least one capacitor to a threshold th2 after waiting time t2 for Equivalent Series Resistance (ESR) screening; and
compare the change in the charge state of the at least one capacitor to a threshold th3 after waiting time t3 for Leakage Current (LC) and Self-Discharge (SD) screening.

3. The system of claim 1 wherein the logic instructions:
compare a second change in the charge state of the at least one capacitor to a threshold th1-low and a threshold th1-high after charging for time t1 for capacitance screening;
compare a charge state of the at least one capacitor to a threshold th2 after waiting time t2 for Equivalent Series Resistance (ESR) screening; and
compare the change in the charge state of the at least one capacitor to a threshold th3 after waiting time t3 for Leakage Current (LC) and Self-Discharge (SD) screening.

4. The system of claim 1 further comprising an output device operatively associated with the controller for reporting to a user a result of the screening of the at least one capacitor.

5. The system of claim 1 further comprising a host computer for identifying to a user a result of the screening of the at least one capacitor.

6. The system of claim 1 wherein the controller receives changes to the at least one threshold from a host computer.

7. The system of claim 1 further comprising a discharge switch operable by the controller after screening operations to discharge the at least one capacitor.

8. A method for screening capacitors comprising:
applying an electrical signal to at least one capacitor;
receiving an electrical input representing a charge state of the at least one capacitor;
waiting a predetermined time period;
receiving a second electrical input representing a second charge state of the at least one capacitor after the waiting operation;
determining a change in charge state of the at least one capacitor; and
comparing the change in charge state of the at least one capacitor to at least one threshold; and
screening the at least one capacitor based on the comparison operation.

9. The method of claim 8 further comprising screening the at least one capacitor for at least one of the following characteristics: capacitance, Equivalent Series Resistance (ESR), Leakage Current (LC), and Self-Discharge (SD).

10. The method of claim 9 wherein capacitance screening includes comparing a charge state of the at least one capacitor to thresholds th1-low and th1-high after charging for time t1.

11. The method of claim 10 wherein ESR screening includes comparing a charge state of the at least one capacitor to a threshold th2 after waiting time t2.

12. The method of claim 11 wherein LC and SD screening includes comparing a change in the charge state of the at least one capacitor to a threshold th3 after waiting time t3.

13. The method of claim 8 further comprising reporting a result of the screening of the at least one capacitor.

14. The method of claim 8 further comprising discharging the at least one capacitor after the screening operation.

15. A method for screening capacitors comprising:
charging at least one capacitor for time t1;
after time t1, comparing a charge state of the at least one capacitor to thresholds th1-low and th1-high for a capacitance screening operation;
after waiting time t2, comparing the charge state of the at least one capacitor to a threshold th2 for an Equivalent Series Resistance (ESR) screening operation; and
after waiting time t3, comparing a change in the charge state of the at least one capacitor to a threshold th3 for a Leakage Current (LC) and Self-Discharge (SD) screening operation.

16. The method of claim 15 further comprising rejecting any capacitor for failing the capacitance screening operation if the charge state is greater than the threshold th1-high.

17. The method of claim 15 further comprising rejecting any capacitor for failing the capacitance screening operation if the charge state is less than the threshold th1-low.

18. The method of claim 15 further comprising rejecting any capacitor for failing the ESR screening operation if the charge state is less than the threshold th2.

19. The method of claim 15 further comprising rejecting any capacitor for failing the LC and SD screening operation if the change in the charge state is greater than the threshold th3.

20. The method of claim 15 wherein the operations are implemented manually by a user.

21. The method of claim 15 wherein all of the screening operations are executed in under one minute.
